(19) United States
(12) Patent Application Publication
(10) Pub. No.: US 2019/0326549 A1
(43) Pub. Date: Oct. 24, 2019

(54) DISPLAY DEVICE AND METHOD FOR MANUFACTURING DISPLAY DEVICE

(71) Applicant: Japan Display Inc., Tokyo (JP)

(72) Inventors: Hiraaki Kokame, Tokyo (JP); Akinori Kamiya, Tokyo (JP); Naoya Kubota, Tokyo (JP)

(21) Appl. No.: 16/453,123

(22) Filed: Jun. 26, 2019

Related U.S. Application Data
(63) Continuation of application No. PCT/JP2017/042785, filed on Nov. 29, 2017.

(30) Foreign Application Priority Data
Jan. 6, 2017 (JP) 2017-001183

(51) Int. Cl. H01L 51/52; H05B 33/04; H05B 33/06; H05B 33/08; H01L 27/32; H01L 51/56

(52) U.S. Cl. CPC H01L 51/5246; H05B 33/04; H05B 33/06; H01L 51/5203; H01L 27/3244; H01L 51/56; H05B 33/0896

(57) ABSTRACT

A display device includes a plurality of pixels arranged on one surface of a substrate within a display region, each of the plurality of pixels including a light emitting element, a partition wall layer including a first partition wall, a second partition wall and a third partition wall, a sealing layer arranged on the plurality of pixels and the partition wall layer, the sealing layer including a first inorganic insulating layer, an organic insulating layer and a second inorganic insulating layer, a protective layer arranged on the sealing layer, and a plurality of connection terminals exposed from the protective layer. The first partition wall surrounds each of the plurality of pixels, the second partition wall surrounds the display region, the third partition wall surrounds the outside of the second partition wall. A groove part is included between the second partition wall and the third partition wall.

### CROSS REFERENCE TO RELATED APPLICATIONS

This application is based upon and claims the benefit of priority from the prior Japanese Patent Application No. 2017-001183, filed on Jan. 6, 2017, and PCT Application No. PCT/JP2017/042785 filed on Nov. 29, 2017, the entire contents of which are incorporated herein by reference.

### FIELD

An embodiment of the present invention is related to a sealing structure of a display device and a method of manufacturing a display device having the sealing structure.

### BACKGROUND

In an organic electroluminescent (referred to as organic EL herein) display device, a light emitting element is arranged in each pixel and an image is displayed by individually controlling light emission. The light emitting element has a structure in which a layer including an organic EL material (also referred to as a “light emitting layer” herein) is sandwiched between a pair of electrodes, one of which is distinguished as an anode and the other being a cathode. When electrons are injected from the cathode into the light emitting layer and holes are injected from the anode, the electrons and holes recombine. In this way, light emitting molecules in the light emitting layer are excited by the excess energy which is emitted and then light is emitted by de-excitation.

In the organic EL display device, an anode in each light emitting element is arranged as a pixel electrode for each pixel, and a cathode is arranged as a common electrode applied with a common potential across a plurality of pixels. The organic EL display device controls the light emission of a pixel by controlling a potential applied to the pixel electrode for each pixel with respect to the potential of the common electrode.

The light emitting layer of the organic EL display device easily deteriorates due to the entrance of moisture, and there is a problem whereby a non-lighting region called a dark spot is generated. In order to solve this problem, many organic EL display devices are arranged with a sealing layer for preventing the entrance of moisture.

For example, an organic EL display device is disclosed in Japanese Laid Open Patent Publication No. 2015-15089 including pixels having a light emitting region arranged in a matrix and a display region having an organic insulating layer formed from an organic insulating material, a periphery circuit region which is a periphery of the display region having an organic insulating layer and being arranged with a circuit using metal wiring or a thin film transistor, and a blocking region formed between the display region and the periphery circuit region, wherein the blocking region has an electrode layer continuously formed from the display region, one of two electrodes covers the display region and cause a light emitting region to emit light, a first blocking region formed only by a layer of an inorganic material from the electrode layer to an insulating substrate which is a base member, and a second blocking region formed only by a plurality of layers forming the first blocking region and a light emitting organic layer.

However, in the case where a process of patterning a sealing layer is included in the manufacturing process of the display device, a function for preventing the entrance of moisture may be deteriorated by etching up to an unintended region of the sealing layer.

### SUMMARY

A display device in an embodiment according to the present invention includes a plurality of pixels arranged on one surface of a substrate within a display region, each of the plurality of pixels including a light emitting element, a partition wall layer including a first partition wall, a second partition wall and a third partition wall, a sealing layer arranged on the plurality of pixels and the partition wall layer, the sealing layer including a first inorganic insulating layer, an organic insulating layer and a second inorganic insulating layer, a protective layer arranged on the sealing layer, and a plurality of connection terminals exposed from the protective layer. The first partition wall surrounds each of the plurality of pixels, the second partition wall surrounds the display region, the third partition wall surrounds the outside of the second partition wall. A groove part is included between the second partition wall and the third partition wall. The organic insulating layer is arranged on the first inorganic insulating layer, the second inorganic insulating layer is arranged on the organic insulating layer. An end part of the organic insulating layer is arranged between the first partition wall and the second partition wall or on the second partition wall, and an end part of the first inorganic insulating layer, the second inorganic insulating layer and the protective layer are each arranged further to the outside than an end part of the second partition wall.

A method for manufacturing display device in an embodiment according to the present invention, the method includes forming a display region including a plurality of pixels, each of the plurality of pixels including a light emitting element, a partition wall layer including a first partition wall covering a periphery edge of each of the plurality of pixels, a second partition wall surrounding the display region, and a third partition wall surrounding the second partition wall, and a plurality of connection terminals on the outside of the third partition wall on one surface of a substrate, forming a sealing layer including a first inorganic insulating layer on the plurality of pixels and the partition wall layer, an organic insulating layer having an end part arranged on an inner side of the second partition wall on the first inorganic insulating layer, and a second inorganic insulating layer on the organic insulating layer, etching the first inorganic insulating layer and the second inorganic insulating layer so that an end part of each is further to the outside than the second partition wall, forming a protective layer on the sealing layer so that an end part thereof is on the third partition wall, and etching the sealing layer exposed from the protective layer using the protective layer as a mask and exposing a plurality of connection terminals.

### BRIEF DESCRIPTION OF DRAWINGS

FIG. 1 is a top view of explaining a structure of a display device of one embodiment of the present invention;

FIG. 2 is a top view of explaining a structure of a display device of one embodiment of the present invention;

FIG. 3 is a cross-sectional view of explaining a structure of a display device of one embodiment of the present invention;

FIG. 4 is a cross-sectional view of explaining a manufacturing method of a display device of one embodiment of the present invention;

FIG. 5 is a cross-sectional view of explaining a manufacturing method of a display device of one embodiment of the present invention;

FIG. 6 is a cross-sectional view of explaining a manufacturing method of a display device of one embodiment of the present invention; and

FIG. 7 is a cross-sectional view of explaining a manufacturing method of a display device of one embodiment of the present invention.

### DESCRIPTION OF EMBODIMENTS

Each embodiment of the present invention is explained below while referring to the drawings. However, the present invention can be implemented in various aspects within a scope that does not depart from the gist of the invention and should not to be interpreted as being limited to the description of the embodiments exemplified below.

Although the drawings may be schematically represented in terms of width, thickness, shape, and the like of each part as compared with their actual mode in order to make explanation clearer, they are only examples and an interpretation of the present invention is not limited. In the present specification and each drawing, the same reference numerals are attached to elements which have previously been explained with reference to preceding figures and to elements having the same function and repeated explanations may be omitted accordingly.

In an embodiment of the present invention, in the case when a single film is processed to form a plurality of films, these films may have different functions and roles. However, the plurality of films is derived from films formed in the same layer by the same process and have the same layer structure and the same material. Therefore, these films are defined as existing in the same layer.

In an embodiment of the present specification, when expressing a mode in which another structure is arranged above a certain structure, in the case where it is simply described as “above”, unless otherwise noted, a case where another structure is arranged directly above a certain structure as if in contact with that structure, and a case where another structure is arranged via another structure above a certain structure, are both included.

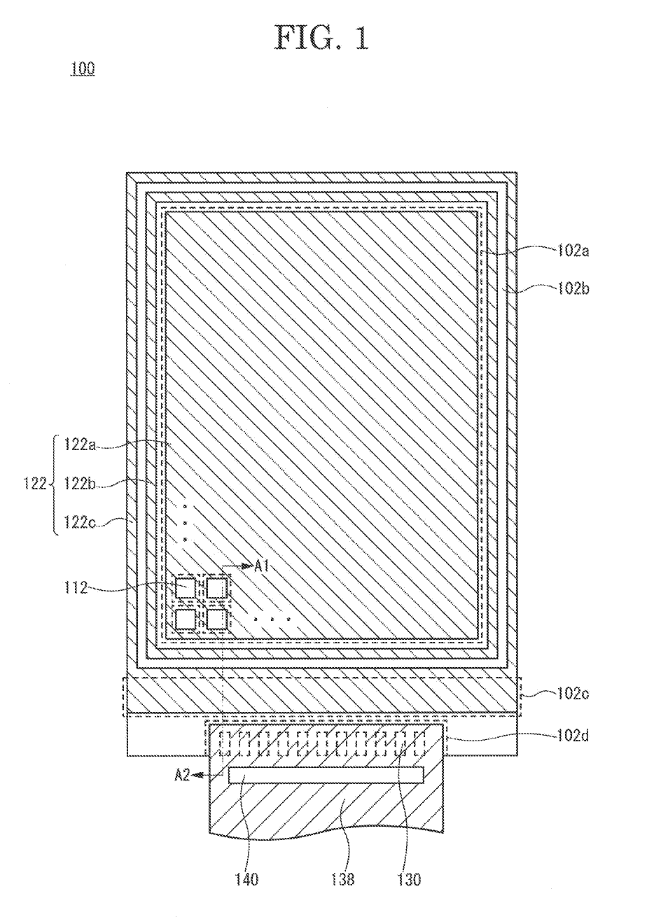

FIG. 1 is a top view of explaining a structure of a display device 100 according to the present embodiment. The display device 100 includes a display region 102a, a periphery edge region 102b, a curved region 102c and a terminal region 102d.

The display region 102a is a region for displaying an image. A plurality of pixels 112 are arranged in the display region 102a. The plurality of pixels 112 is arranged in a matrix shape in two directions which cross each other. In the present embodiment, the plurality of pixels 112 is arranged in a matrix shape in two directions which are orthogonal to each other. Each of the plurality of pixels 112 is arranged with a light emitting element. FIG. 1 further shows an end part of a partition wall layer 122 described herein. The partition wall layer 122 has a first partition wall 122a arranged on the periphery of each of the plurality of pixels 112 in the display region 102a.

The periphery region 102b is a region which contacts the periphery edge of the display region 102a and surrounds the display region 102a. A drive circuit for controlling light emission of the plurality of pixels 112 may also be arranged in the periphery region 102b. The partition wall layer 122 has a second partition wall 122b and a third partition wall 122c in the periphery region 102b. A gape exists between the second partition wall 122b and the first partition wall 122a, and the second partition wall 122b has a periphery shape which surrounds the first partition wall 122a. A gap exists between the third partition wall 122c and the second partition wall 122b and the third partition wall 122c has a periphery shape which surrounds the second partition wall 122b.

The curved region 102c is an optional configuration and is a region in which the display device 100 can be bent. In the display device 100, by bending at an arbitrary straight line passing through the inside of the curved region 102c, it is possible to fold the terminal region 102d on the rear side of the display surface of the display region 102a.

The terminal region 102d is a region for connecting the display device 100 and a flexible printed circuit base (FPC base) 138 and the like. The terminal region 102d is arranged along one side of the display device 100 and a plurality of connection terminals 130 is arranged. A driver IC 140 arranged with a circuit for processing a video signal may be mounted on the FPC base 138.

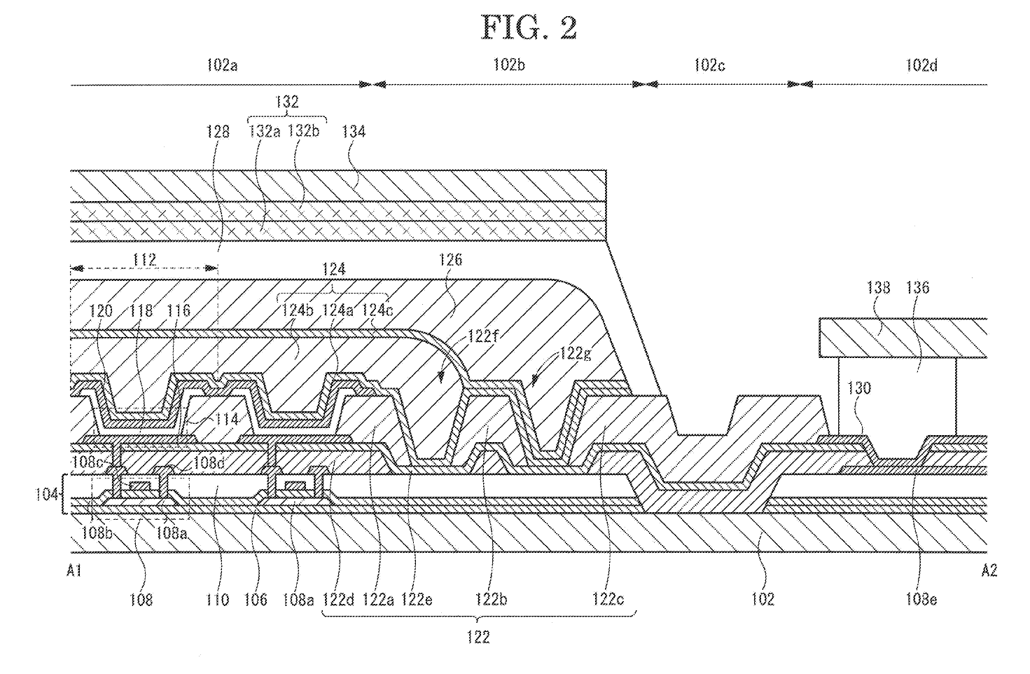

FIG. 2 is a cross-sectional view of explaining the structure of the display device 100 according to the present embodiment and shows the structure of a cross-section along the line A1-A2 shown in FIG. 1. The display device 100 includes a substrate 102, a circuit layer 104, the plurality of pixels 112, the partition wall layer 122, a sealing layer 124, a first protective layer 126, a second protective layer 128, a plurality of connection terminals 130, a polarizing plate 132 and a cover film 134. The sealing layer 124 is formed including a first inorganic insulating layer 124a, an organic insulating layer 124b and a third inorganic insulating layer 124c. In addition, the first protective layer 126 and the second protective layer 128 are arranged on an upper layer of the sealing layer 124. In addition, the plurality of connection terminals 130 is arranged on the outside of the first protective layer 126.

The substrate 102 supports various elements such as the circuit layer 104 and the plurality of pixels 112 which are arranged on the one surface side of the substrate 102. It is possible to use glass, quartz, plastic, metal and ceramic or the like as the material of the substrate 102.

A base member may be formed on the substrate 102 in the case where the display device 100 is imparted with flexibility. In this case, the substrate 102 is also called a support substrate. The base member is a flexible insulating layer. Specific materials of the base member can include, for example, materials selected from polymeric materials exemplified by polyimide, polyamide, polyester and polycarbonate.

The circuit layer 104 is arranged on one surface of the substrate 102 and includes an under coat layer 106, a transistor 108 and an interlayer insulating layer 110. The circuit layer 104 is further arranged with a pixel circuit which includes the transistor 108, and a drive circuit and the like (not shown in the figure). The pixel circuit is arranged in each of the plurality of pixels 112 which are arranged in the display region 102a and controls the light emission of the light emitting element 114. The drive circuit is arranged in the periphery region 102b and drives the pixel circuit.

The under coat layer 106 has an optional configuration and is arranged on a first surface of the substrate 102 on which each layer can be arranged. The under coat layer 106 is a layer for preventing impurities such as alkali metal diffusing from the substrate 102 (and the base member) to the transistor 108 and the like. The material of the under coat layer 106 can include an inorganic insulating material.

Silicon nitride, silicon oxide, and silicon oxynitride or the like can be included as the inorganic insulating material. In the case when the concentration of impurities in the substrate 102 is small, it is not necessary to arrange the under coat layer 106 or it may be formed to cover only a part of the substrate 102.

The transistor 108 includes a semiconductor layer 108a, a gate insulating layer 108b, a gate electrode 108c and a source/drain electrode 108d. The semiconductor layer 108a is arranged in an island shape on the under coat layer 106. For example, it is possible to use a Group 14 element such as silicon or an oxide semiconductor as a material of the semiconductor layer 108a. It is possible to include an oxide of a Group 13 element such as indium or gallium as the oxide semiconductor and examples thereof include a mixed oxide of indium and gallium (IGO). In the case where an oxide semiconductor is used for the semiconductor layer 108a, the semiconductor layer 108a may further include a Group 12 element and an example thereof includes a mixed oxide (IGZO) including indium, gallium and zinc. There is no limitation to the crystallinity of the semiconductor layer 108a, and it may be one of a single crystal, polycrystal, microcrystalline or amorphous.

The gate insulating layer 108b is arranged on the semiconductor layer 108a. In the present embodiment, the gate insulating layer 108b is arranged across the plurality of transistors 108. However, the gate insulating layer 108b may also be arranged at least in a region which overlaps the gate electrode 108c. It is possible to use a material such as silicon nitride, silicon oxide, or silicon oxynitride as a material of the gate insulating layer 108b similar to the under coat layer 106. The gate insulating layer 108b may also have a single layer structure or a structure in which films formed of these inorganic insulating materials are stacked.

The gate electrode 108c overlaps the semiconductor layer 108a interposed by the gate insulating layer 108b. In the semiconductor layer 108a, a region which overlaps the gate electrode 108c is a channel region. It is possible to use a metal such as titanium, aluminum, copper, molybdenum, tungsten, tantalum or an alloy thereof as a material of the gate electrode 108c. It is possible to form gate electrode 108c using a single layer of any of these materials or to have a stacked structure of a plurality of materials selected from these. For example, it is possible to adopt a structure in which a highly conductive metal such as aluminum or copper is sandwiched by metals having a relatively high melting point such as titanium, tungsten or molybdenum.

The interlayer insulating layer 110 is arranged on the gate electrode 108c. It is possible to use a material which can be used for the under coat layer 106 as a material of the interlayer insulating layer 110 and a single layer structure or a stacked structure selected from these materials can be used.

The source/drain electrode 108d is arranged on the interlayer insulating layer 110. The source/drain electrode 108d is electrically connected to a source/drain region of the semiconductor layer 108a at an opening which is arranged in the interlayer insulating layer 110 and the gate insulating layer 108b. Terminal wiring 108e are further arranged on the interlayer insulating layer 110. That is, as is shown in FIG. 2, the terminal wiring 108e which is arranged in the terminal region 102d can exist in the same layer as the source/drain electrode 108d. In addition, the present invention is not limited to this structure, and the terminal wiring 108e may be formed to exist in the same layer as the gate electrode 108c (not shown in the figure).

Although the transistor 108 is exemplified as being a top gate type transistor in FIG. 2, the structure of the transistor 108 is not limited and a bottom gate type transistor, a multi-gate type transistor which includes a plurality of gate electrodes 108c, and a dual gate type transistor having a structure in which two gate electrodes 108c sandwich upper and lower semiconductor layers 108a are also possible. In addition, although an example in which one transistor 108 is arranged in each pixel 112 is shown in FIG. 2, each pixel 112 may further include a plurality of transistors 108 and a semiconductor element such as a capacitor.

Each of the plurality of pixels 112 includes a light emitting element 114. The light emitting element 114 has a layer structure in which a first electrode 116, a light emitting layer 118 and a second electrode 120 are stacked from the substrate 102 side. Carriers are injected from the first electrode 116 and the second electrode 120 into the light emitting layer 118, and carrier recombination occurs within the light emitting layer 118. An excited state of light emitting molecules in the light emitting layer 118 occurs due to the recombination of carriers and light emission is obtained via the process of relaxation to a ground state.

The first electrode 116 is arranged on layer on a planarization insulating layer 122d. The first electrode 116 covers an opening which is arranged in the planarization insulating layer 122d and the inorganic insulating layer 122e, and is arranged so as to be electrically connected to the source/drain electrode 108d. In this way, a current is supplied to the light emitting element 114 via the transistor 108. In the case when light emitted from the light emitting element 114 is extracted from the second electrode 120, the material of the first electrode 116 is selected from materials which can reflect visible light. In this case, the first electrode 116 uses a metal which has a high reflectance such as silver or aluminum or an alloy thereof. Alternatively, a conductive oxide layer with translucency is formed on the layer which includes these metals and alloys. ITO and IZO are examples of the conductive oxide. In the case when light emission from the light emitting element 114 is extracted from the first electrode 116, ITO or IZO can be used as the material of the first electrode 116.

The light emitting layer 118 is arranged so as to cover the first electrode 116 and the first partition wall 122a. It is possible to appropriately select the structure of the light emitting layer 118 and can be formed by combining, for example, a carrier injection layer, a carrier transport layer, the light emitting layer 118, a carrier blocking layer and an exciton blocking layer and the like. The light emitting layer 118 can be formed so as to include different materials for each pixel 112. By appropriately selecting a material which is used for the light emitting layer 118, it is possible to obtain different emission colors for each pixel 112. Alternatively, the structure of the light emitting layer 118 may be the same between pixels 112. In this type of structure, since the same emission color is output from the light emitting layer 118 of each pixel 112, for example, the light emitting layer 118 may formed to be able to emit white light and various colors (for example, red, green and blue) can be extracted from the pixels 112 respectively by using a color filter.

The second electrode 120 is arranged on the light emitting layer 118. The second electrode 120 may also be arrange in common to a plurality of pixels 112 as in the present embodiment. In the case when light emitted from the light emitting element 114 is extracted from the second electrode 120, the material of the second electrode 120 is selected from conductive oxides having translucency such as

ITO. Alternatively, the metals described above can be formed to a thickness which allows visible light to pass through. In this case, a conductive oxide having translucency may be further stacked.

The partition wall layer 122 is arranged on the first surface of the substrate 102. The partition wall layer 122 includes a first partition wall 122a, a second partition wall 122b, a third partition wall 122c, a planarization insulating layer 122d and an inorganic insulating layer 122e.

The first partition wall 122a is arranged between adjacent pixels 112 among the plurality of pixels 112 in planar view, and surrounds each of the plurality of pixels 112. The first partition wall 122a covers the periphery edge of the surface of the first electrode 116 on the light emitting layer 118 side. By covering the periphery edge of the first electrode 116, it is possible for the first partition wall 122a to prevent the light emitting layer 118 and the second electrode 120 provided thereon from disconnection. In a planar view, a region where the first electrode 116 and the light emitting layer 118 contact each other is a light emitting region.

The second partition wall 122b has a gap between it and the first partition wall 122a in a planar view and has a periphery shape which surrounds the first partition wall 122a. It can be said that the second partition wall 122b is arranged so as to surround the display region. In this way, a periphery shaped groove 122f is formed between the second partition wall 122b and the first partition wall 122a. Although described in detail herein, when the organic insulating layer 124b which forms the sealing layer 124 is formed in the manufacturing process, it is necessary that the organic insulating layer 124b covers the display region 102a and is selectively formed in a region within the surface of the substrate 102 so as not to spread to an end part of the substrate 102. When the organic insulating layer 124b spreads to the end part of the substrate 102, it is feared that moisture may enter the display device 100 from the end part via the organic insulating layer 124b. The organic insulating layer 124b is selectively applied to the display region 102a using an inkjet method for example. In this case, the second partition wall 122b has a blocking function so that the organic insulating layer 124b does not spread to the outside thereof.

As a result, the second partition wall 122b is arranged so that the gap between the second partition wall 122b and the first partition wall 122a is 10 μm or more and 500 μm or less, preferably 10 μm or more and 200 μm or less. If the gap between the second partition wall 122b and the first partition wall 122a is smaller than this range, a sufficient blocking function cannot be obtained when forming the organic insulating layer 124b. When the gap between the second partition wall 122b and the first partition wall 122a is larger than this range, narrowing of the frame of the display device 100 is inhibited. In addition, it is preferred that the width of the second partition wall 122b is 5 μm or more and 200 μm or less. If the width of the second partition wall 122b is smaller than this range, it becomes difficult to form a second side wall with a sufficient height in the manufacturing process. If the width of the second partition wall 122b is larger than this range, narrowing of the frame of the display device 100 is inhibited. In addition, the second partition wall 122b preferably has a maximum height of 1 μm or more and 5 μm or less. If the height of the second partition wall 122b is smaller than this range, a sufficient blocking function cannot be obtained when the organic insulating layer 124b is applied. When the height of the second partition wall 122b is larger than this range, it becomes difficult to form the partition wall layer 122.

The third partition wall 122c has a gap between it and the second partition wall 122b in a planar view and has a periphery shape which surrounds the second partition wall 122b. In this way, a periphery shaped groove 122g is formed between the third partition wall 122c and the second partition wall 122b. Although described in detail herein, when the sealing layer 124 which covers the plurality of connection terminals 130 is patterned and the plurality of connection terminals 130 is exposed in the manufacturing process, the sealing layer 124 is etched using the first protective layer 126 as a mask. The end part of the first protective layer 126 recedes when this etching is performed. If the end part of the first protective layer 126 recedes too much, there is a danger that etching is performed up to a region where three layers of the first inorganic insulating layer 124a, the organic insulating layer 124b and the second inorganic insulating layer 124c are stacked during etching of the sealing layer 124 and that the organic insulating layer 124b may be exposed. When the organic insulating layer 124b is exposed, moisture enters from the organic insulating layer 124b and subsequently passes through the first inorganic insulating layer 124a which deteriorates the light emitting layer 118. In this way, the yield and reliability of the display device 100 deteriorate. Since the first inorganic insulating layer 124a is arranged on the partition wall layer 122 which has unevenness, a crack or the like easily occurs which can form an entrance path for moisture.

As a result, if the third partition wall 122c is arranged and the first protective layer 126 is formed so that the end part is arranged on the third partition wall 122c, it is possible to increase the film thickness of the first protective layer 126 in the vicinity of the end part using the groove part 122g between the second partition wall 122b and the third partition wall 122c. In this way, it is possible to prevent the end part of the first protective layer 126 from receding when etching the sealing layer 124. In this way, it is possible to perform etching up to an unintended region of the sealing layer 124, and the it is possible to prevent the organic insulating layer 124b from being exposed.

In addition, in a process described herein, the first inorganic insulating layer 124a and the second inorganic insulating layer 124b are removed using the first protective layer 126 as a mask. In this case, if the first protective layer 126 inadvertently flows out as far as the end part vicinity of the substrate 102, the region where the first inorganic insulating layer 124a and the second inorganic insulating layer 124c are not removed expands. Since the distance between the display region 102a and the terminal region 102d is reduced when frame narrowing proceeds, the exposure of the connection terminal 130 may be inhibited. The blocking effect of the first protective layer 126 can be expected by using the third partition wall 122c and the groove part 122g.

As a result, the third partition wall 122c is arranged so that the gap between the third partition wall 122c and the second partition wall 122b is 10 μm or more and 500 μm or less, preferably 10 μm or more and 200 μm or less. If the gap between the third partition wall 122c and the second partition wall 122b is smaller than this range, it is not possible to sufficiently secure a region having a sufficient thickness in the end part vicinity of the first protective layer 126, and the blocking function for preventing the end part from receding is not sufficiently obtained. If the gap between the third partition wall 122c and the second partition wall 122b is larger than this range, narrowing of the frame of the display device 100 is inhibited. In addition, the third partition wall 122c is preferred to have a maximum height of 1 μm or more and 5 μm or less. If the height of the third partition wall 122c is smaller than this range, the film thickness in the end part vicinity of the first protective layer 126 cannot be made sufficiently thick, and the function for preventing the end part of the first protective layer 126 from receding cannot be sufficiently obtained. If the height of the third partition wall 122c is larger than this range, it becomes difficult to form the partition wall layer 122.

Among the partition wall layers 122, the first partition wall 122a, the second partition wall 122b and the third partition wall 122c are separated from each other in a planar view. For example, it is possible to use organic insulation materials such as an epoxy resin and an acrylic resin as a material of the first partition wall 122a, the second partition wall 122b and the third partition wall 122c.

The planarization insulating layer 122d is arranged in a layer on the circuit layer 104 and in a layer below the light emitting element 114. The planarization insulating layer 122d absorbs unevenness caused by a semiconductor element such as the transistor 108 and provides a flat surface. A material that can be used for the first partition wall 122a, the second partition wall 122b and the third partition wall 122c can be used as a material of the planarization insulating layer 122d.

The inorganic insulating layer 122e is an optional member and has a function of protecting a semiconductor element such as the transistor 108. Furthermore, a capacitor can be formed between the first electrode 116 of the light emitting element 114 and an electrode (not shown in the figure) which is formed to sandwich the first electrode 116 and the inorganic insulating layer 122e in layer below the inorganic insulating layer 122e.

A plurality of openings is arranged in the planarization insulating layer 122d and the inorganic insulating layer 122e. One of the openings is arranged in order to electrically connect the first electrode 116 of the light emitting element 114 and the source/drain electrode 108d of the transistor 108. One of the other openings is arranged so that a part of the terminal wiring 108e is exposed. The terminal wiring 108e which is exposed by one of the other openings is connected to the FPC base 138 by an anisotropic conductive film 136 for example.

The sealing layer 124 is arranged on a layer on the plurality of pixels 112 and the partition wall layer 122. The sealing layer 124 includes a first inorganic insulating layer 124a, an organic insulating layer 124b and a second inorganic insulating layer 124c.

The first inorganic insulating layer 124a covers an uneven surface caused by the partition layer wall 122. An end part of the first inorganic insulating layer 124a is arranged on the outside the second partition wall 122b and is arranged at a position on the third partition wall 122c or in a position overlapping the groove part 122g. That is, the first inorganic insulating layer 124a covers the bottom surface and the partition wall of the groove part 122f between the first partition wall 122a and the second partition wall 122b. Furthermore, the first inorganic insulating layer 124a covers the bottom surface and the side wall of the groove part 122g between the second partition wall 122b and the third partition wall 122c.

The first inorganic insulating layer 124a has at least the following two functions. First, the organic insulating layer 124b which is arranged in layer on the first inorganic insulating layer 124a and in which moisture easily passes through is arranged so as not to contact the light emitting element 114. In this way, moisture which is included in the organic insulating layer 124b or moisture which has entered the organic insulating layer 124b from the outside of the display device 100 can be prevented from reaching and deteriorating the light emitting layer 118. Secondly, the first inorganic insulating layer 124a is arranged so that an entrance path for moisture to enter between second partition wall 122b and the third partition wall 122c through an organic material is not generated. In this way, the moisture in the third partition wall 122c or the moisture which is entered the third partition wall 122c from the outside of the display device 100 can be prevented from entering the inner side from the second partition wall 122b and degrading the light emitting layer 118.

An insulating material having low moisture permeability is preferred as a material of the first inorganic insulating layer 124a. For example, silicon oxide, silicon nitride, silicon oxynitride, aluminum oxide, aluminum nitride and aluminum oxynitride or the like can be used as a specific material of the first inorganic insulating layer 124a. In addition, a structure in which a plurality of materials selected from these are stacked may also be used.

The organic insulating layer 124b is arranged on a layer on the first inorganic insulating layer 124a. An end part of the organic insulating layer 124b is also arranged between the first partition wall 122a and the second partition wall 122b or on the second partition wall 122b. The organic insulating layer 124b is arranged in order to planarize unevenness caused by the partition wall layer 122 or the like.

When the unevenness is not sufficiently planarized and the second inorganic insulating layer 124c is arranged on the organic insulating layer 124b, the second inorganic insulating layer 124c can not sufficiently cover the unevenness which remains on the organic insulating layer 124b, defects such as cracks may occur in the inorganic insulating layer 124c and an entrance path for moisture may be created from such a defect.

The second inorganic insulating layer 124c is arranged on the organic insulating layer 124b. An end part of the second inorganic insulating layer 124c is also arranged on the outside of the second partition wall 122b and overlaps on the third partition wall 122c or the groove part 122g. In the present embodiment, the second inorganic insulating layer 124c is arranged along an end part of the first inorganic insulating layer 124a. In addition, since the end parts of the first inorganic insulating layer 124a and the second inorganic insulating layer 124c are arranged on the third partition wall 122c, the second partition wall 122b can be securely covered by the first inorganic insulating layer 124a and the second inorganic insulating layer 124c, and it is possible to increase the effect of preventing moisture from entering the display region 102a. In addition, the organic insulating layer 124b is sealed by the first inorganic insulating layer 124a and the second inorganic insulating layer 124c. By providing this type of structure, it is possible to block an entrance path for moisture from the outside to the inside of the display device 100 via the organic insulating layer 124b. An insulating material having low moisture permeability is preferably used as a material of the second inorganic insulating layer 124c, and it is possible to use the same material as the first inorganic insulating layer 124a.

Furthermore, it is not absolutely necessary that the end part of the second inorganic insulating layer 124c has to be arranged along the end part of the first inorganic insulating layer 124a. It is sufficient that the sealing layer 124 is formed so that the organic insulating layer 124b is sealed by the first inorganic insulating layer 124a and the second inorganic insulating layer 124c.

The first protective layer 126 is arrange on a layer on the sealing layer 124, that is, the second inorganic insulating layer 124c.

An end part of the first protective layer 126 is also arranged on the outside of the second partition 122b, that is, on the third partition wall 122c. In the present embodiment, the first protective layer 126 is arranged along the end part of the first inorganic insulating layer 124a. The first protective layer 126 also fills the groove part 122g between the second partition wall 122b and the third partition wall 122c. In this way, the thickness of the first protective layer 126 in the groove part 122g is thicker than on the second partition wall 122b and the third partition wall 122c. The same material as the material which can be used for the organic insulating layer 124b described can be used as a material of the first protective layer 126. The unevenness on the upper surface of the first protective layer 126 is smaller than the unevenness in the partition wall layer 122, and in particular, the difference between the height of the upper surface of the first protective layer 126 on the outer end of the second partition wall 122b and the height of the upper surface of the first protective layer 126 on the inner end of the third partition wall 122c is smaller than the depth of the groove part 122g.

The second protective layer 128 has an optionally configuration and physically protects the display device 100. A polymer material such as an ester, an epoxy resin or an acrylic resin can be included as a material of the second protective layer 128. The second protective layer 128 can be formed by applying a printing method or a laminating method.

The plurality of connection terminals 130 is arranged on one surface of the substrate 102. Each of the plurality of connection terminals 130 is electrically connected to a connection wiring via an opening which is arranged in the inorganic insulating layer 122e and the planarization insulating layer 122d. The plurality of connection terminals 130 is also arranged on the outside of the first protective layer 126 in a planar view.

The polarization plate 132 can have a stacked structure, for example, of a λ/4 plate 132a and a linear polarization plate 132b arranged thereon. When light incident from the outside of the display device 100 passes through the linear polarization plate 132b and passes through the λ/4 plate 132a after becoming linearly polarized light, it becomes clockwise circularly polarized light. When this circularly polarized light is reflected by the first electrode 116, it becomes counterclockwise circularly polarized light, and this again becomes linearly polarized light by passing through the λ/4 plate 132a. The polarization plane of the linearly polarized light in this case is orthogonal to the linearly polarized light before reflection. Therefore, it cannot pass through the linear polarization plate 132b. As a result, the reflection of external light is suppressed by arranging the polarization plate 132, and it is possible to provide an image with high contrast.

The cover film 134 is an optionally member, but in the present embodiment, is arranged on a layer on the polarization plate 132. The cover film 134 physically protects the polarization plate 132.

According to the structure of the display device 100, it is possible to prevent deterioration of the sealing layer 124 in the manufacturing process. In this way, it is possible to provide the display device 100 with improved manufacturing yield and reliability.

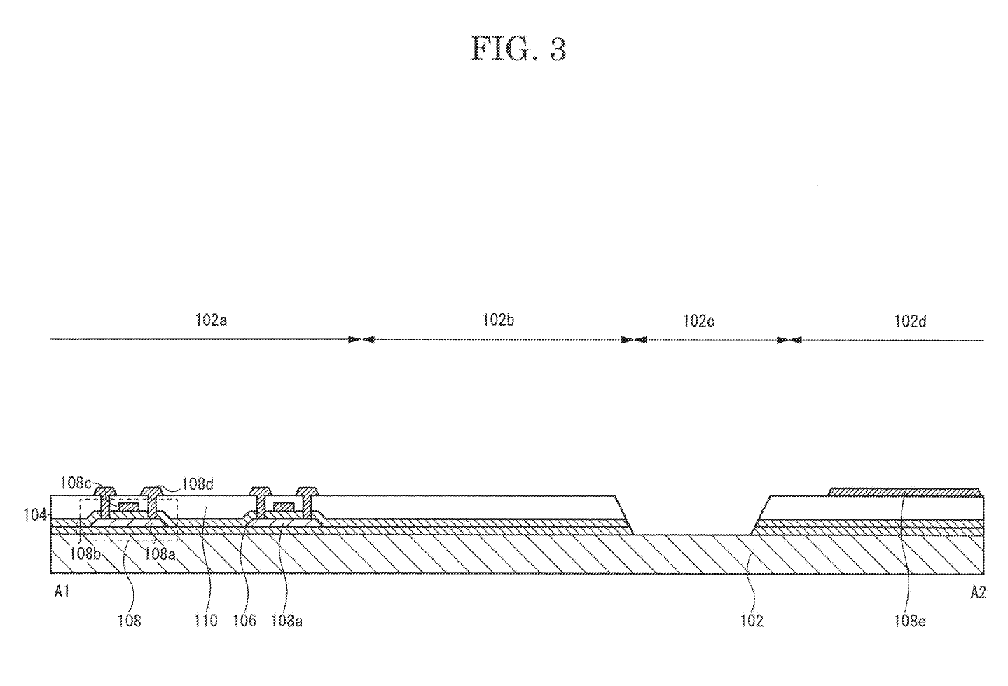

A method of manufacturing the display device 100 according to the present embodiment is explained in detail. FIG. 3 to FIG. 7 are cross-sectional views of explaining a method of manufacturing the display device 100 according to the present embodiment.

The substrate 102 supports various elements such as the transistor 108 which is included in the circuit layer 104 which is arranged on one surface side of the substrate 102. A material which has heat resistance to the process temperature of various elements formed on the substrate 102 and chemical stability with respect to chemicals used in the process may be used for the substrate 102. Glass, quartz, plastic, metal and ceramic and the like can be included as the material of the substrate 102.

In the case where the display device 100 is imparted with flexibility, a base member may be formed on the substrate 102. In this case, the substrate 102 is also called a support substrate. The base member is a flexible insulating layer. For example, materials selected from polymeric materials exemplified by polyimide, polyamide, polyester and polycarbonate can be included as specific materials of the base member. The base member can be formed, for example, by applying a wet film forming method such as a printing method, an inkjet method, a spin coating method, a dip coating method or a laminating method.

A method for forming the circuit layer 104 on one surface of the substrate 102 is explained while referring to FIG. 3. First, an under coat layer 106 is formed. It is possible to include an inorganic insulating material as the material of the under coat layer 106. Silicon nitride, silicon oxide, and silicon oxynitride or the like can be included as the inorganic insulating material. It is possible to form the under coat layer 106 with a single layer structure or a stacked layer structure by applying a chemical vapor deposition method (CVD method) or a sputtering method and or the like. Furthermore, the under coat layer 106 is an optional member, it is not absolutely necessary to arrange the under coat layer 106.

A semiconductor layer 108a is formed. The semiconductor layer 108a may formed from a Group 14 element such as the silicon described above, or the semiconductor layer 108a may formed from an oxide semiconductor. In the case where the semiconductor layer 108a is formed from silicon material, the semiconductor layer 108a may be formed by a CVD method using a silane gas or the like as a raw material. Crystallization by a heat treatment or irradiation with light such as a laser may be performed on the amorphous silicon obtained in this way. In the case where the semiconductor layer 108a is formed from an oxide semiconductor, the semiconductor layer 108a can be formed by a sputtering method or the like.

A gate insulating layer 108b is formed covering the semiconductor layer 108a. The gate insulating layer 108b can be formed with either a single layer structure or a stacked layer structure and using the same method as the under coat layer 106.

A gate electrode 108c is formed on the gate insulating layer 108b. A metal such as titanium, aluminum, copper, molybdenum, tungsten or tantalum or an alloy thereof can be used for the gate electrode 108c. The gate electrode 108c can be formed with single layer of any of these materials, or a stacked structure of a plurality of materials selected from these materials. For example, it is possible to adopt a structure in which a highly conductive metal such as aluminum or copper is sandwiched between metals which have a relatively high melting point such as titanium, tungsten or molybdenum. The gate electrode 108c can be formed using a sputtering method or a CVD method.

An interlayer insulating layer 110 is formed on the gate electrode 108c. The interlayer insulating layer 110 is arranged on an upper layer of the gate electrode 108c. A material which can be used for the under coat layer 106 can be used as a material of the interlayer insulating layer 110, and a single layer structure or a stacked structure selected from these materials can be used. The interlayer insulating layer 110 can be formed using the same method as the under coat layer 106. In the case where a stacked structure is provided, for example, a layer including an inorganic material may be stacked after forming a layer including an organic material.

Etching is performed on the interlayer insulating layer 110 and the gate insulating layer 108b and an opening which reaches the semiconductor layer 108a is formed. The opening can be formed, for example, by performing plasma etching in a gas which includes a fluorine-containing hydrocarbon. Furthermore, the under coat layer 106, the gate insulating layer 108b and the interlayer insulating layer 110 of the circuit layer 104 in a curved region 102c are removed in advance in the same process. Defects such as cracks easily occur in inorganic insulating materials due to bending, and there is concern that an entrance path for moisture may be generated due to these defects. Therefore, it is preferred to remove the inorganic insulating material in the curved region 102c.

A metal layer is formed so that the opening is covered and a source/drain electrode 108d is formed by performing etching and molding. In the present embodiment, the terminal wiring 108e is formed at the same time as the formation of the source/drain electrode 108d. Therefore, it is possible for the source/drain electrode 108d and the terminal wiring 108e to exist in the same layer. It is possible to provide the metal layer with the same structure as the gate electrode 108c, and it is possible to form the metal layer using the same method as the formation of the gate electrode 108c.

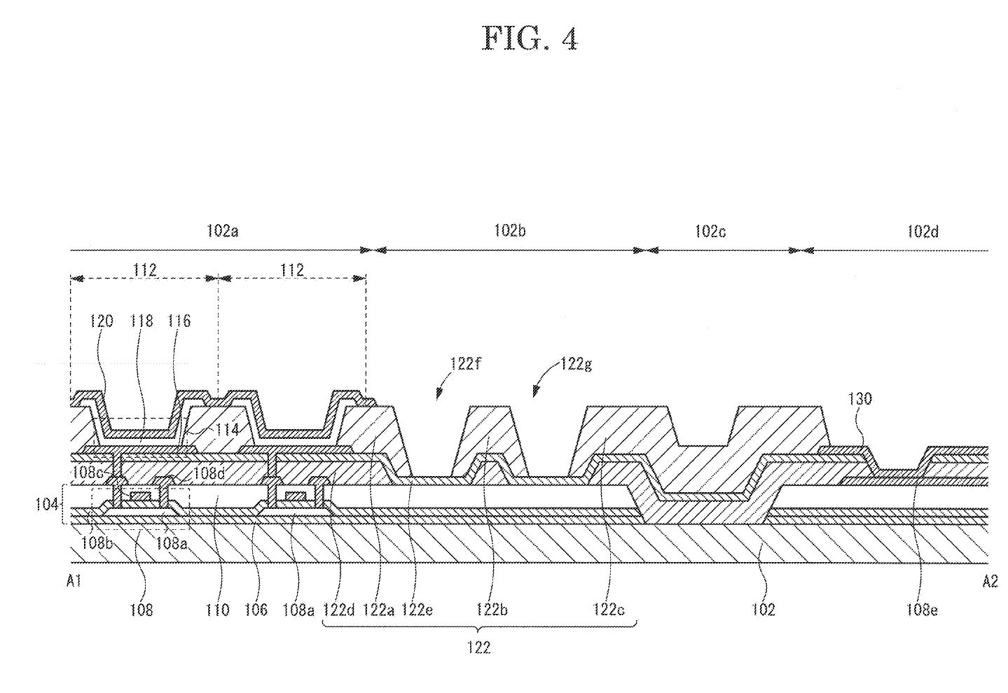

A method for forming the plurality of pixels 112, the partition wall layer 122 and the plurality of connection terminals 130 on one surface of the substrate 102 is explained while referring to FIG. 4. Each of the plurality of pixels 112 includes a light emitting element 114. Here, the partition wall layer 122 includes a first partition wall 122a, a second partition wall 122b, a third partition wall 122c, a planarization insulating layer 122d and an inorganic insulating layer 122e. The first partition wall 122a is arranged around the periphery of each of the plurality of pixels 112, the second partition wall 122b surround the first partition wall 122a, and the third partition wall 122c surrounds the second partition wall 122b. The connection terminal 130 is arranged on the outside of the third partition wall 122c.

The planarization insulating layer 122d is formed. The planarization insulating layer 122d is formed so as to cover the source/drain electrode 108d and the terminal wiring 108e. The planarization insulating layer 122d has a function for absorbing any unevenness and inclines caused by the transistor 108 and the terminal wiring 108e and the like, and to provide a flat surface. It is possible to use an organic insulating material as a material of the planarization insulating layer 122d. Examples of the organic insulating material include polymer materials such as epoxy resin, acrylic resin, polyimide, polyamide, polyester, polycarbonate and poly-siloxane. It is possible to use a wet film formation method or the like as the film formation method.

An inorganic insulating layer 122e is formed on the planarization insulating layer 122d. As is described above, the inorganic insulating layer 122e not only functions as a protective layer with respect to the transistor 108, but also has function as a dielectric film of a capacitor with the first electrode 116 of the light emitting element 114 which is formed later. Therefore, it is preferred to use a material which has a relatively high dielectric constant. For example, it is possible to use silicon nitride, or silicon oxynitride and the like. A CVD method or a sputtering method can be applied as a film formation method.

The inorganic insulating layer 122e and the planarization insulating layer 122d are etched to form openings using the source/drain electrode 108d and the terminal wiring 108e as etching stoppers. Subsequently, the first electrode 116 and the connection terminal 130 are formed so as to cover these openings.

In the case when light emitted from the light emitting element 114 is extracted from the second electrode 120, the first electrode 116 is formed so that visible light is reflected. In this case, a metal which has a high reflectance such as silver or aluminum or an alloy thereof is used for the first electrode 116. Alternatively, a conductive oxide layer which has translucency is formed on the layer which includes these metals and alloys. Examples of the conductive oxide include

ITO and IZO. In the case where light emitted from the light emitting element 114 is extracted from the first electrode 116, the first electrode 116 may be formed using ITO or IZO.

In the present embodiment, the first electrode 116 and a connection electrode are formed on the inorganic insulating layer 122e. Therefore, for example, it is possible to form a layer of the metal described above so as to cover the opening, then form a layer including a conductive oxide that allows visible light to pass through, and form the first electrode 116 and the connection terminal 130 by processing by etching.

The first partition wall 122a, the second partition wall 122b and the third partition wall 122c are formed. The first partition wall 122a can absorb any steps caused by an end part of the first electrode 116 and can electrically disconnect first electrodes 116 of adjacent pixels 112 from each other.

When the organic insulating layer 124b which forms the sealing layer 124 in a later manufacturing process is formed, it is necessary that the organic insulating layer 124b is formed covering the display region 102a and is selectively formed in a region within the surface of the substrate 102 so that it does not spread to the end part of the substrate 102. The organic insulating layer 124b is selectively formed in the display region 102a using, for example, an inkjet method. In this case, the second partition wall 122b has a blocking function so that the organic insulating layer 124b does not spread to the outside thereof.

In addition, when the sealing layer 124 is patterned and the plurality of connection terminals 130 is exposed in a later manufacturing process, the sealing layer 124 is etched using the first protective layer 126 as a mask. The end part of the first protective layer 126 may recede during the etching process. When the end part of the first protective layer 126 recedes too much, in the etching of the sealing layer 124, etching is performed up to the region where the three layers of the first inorganic insulating layer 124a, the organic insulating layer 124b and the second inorganic insulating layer 124c are stacked and there is a concern that the organic insulating layer 124b may be exposed. When the organic insulating layer 124b is exposed, it can become an entrance path for moisture, and when moisture which has entered the organic insulating layer 124b passes through the first inorganic insulating layer 124a, the light emitting layer 118 deteriorates. In this way, the yield and reliability of the display device 100 deteriorate. Since the first inorganic insulating layer 124a is arranged on the partition wall layer 122 which has unevenness, a crack or the like easily occurs which can become an entrance path for moisture.

At least the film thickness in the end part vicinity of the first protective layer 126 may be increased in order to suppress receding of the end part of the first protective layer 126. The third partition wall 122c is arranged for this purpose, and by filling the groove part 122g between the third partition wall 122c and the second partition wall 122b with the first protective layer 126, the film thickness of the end part vicinity of the first protective layer 126 becomes thicker.

It is possible to form the first partition wall 122a, the second partition wall 122b and the third partition wall 122c using a wet film forming method using a material which can be used for the planarization insulating layer 122d such as an epoxy resin or an acrylic resin.

The light emitting layer 118 and the second electrode 120 are formed so as to cover the first electrode 116 and the partition wall layer 122. The light emitting layer 118 mainly includes an organic compound and can be formed by applying a wet film forming method such as an inkjet method or a spin coating method, or a dry film forming method such as evaporation and the like.

In the case when light emitted from the light emitting element 114 is extracted from the first electrode 116, a metal such as aluminum, magnesium, silver or an alloy thereof may be used as a material for the second electrode 120. On the other hand, in the case when light emitted from the light emitting element 114 is extracted from the second electrode 120, a conductive oxide which has translucency such as ITO may be used as a material for the second electrode 120. Alternatively, it is possible to form the second electrode 120 to a thickness which that allows visible light to pass through the metals described above. In this case, a conductive oxide having translucency may be further stacked.

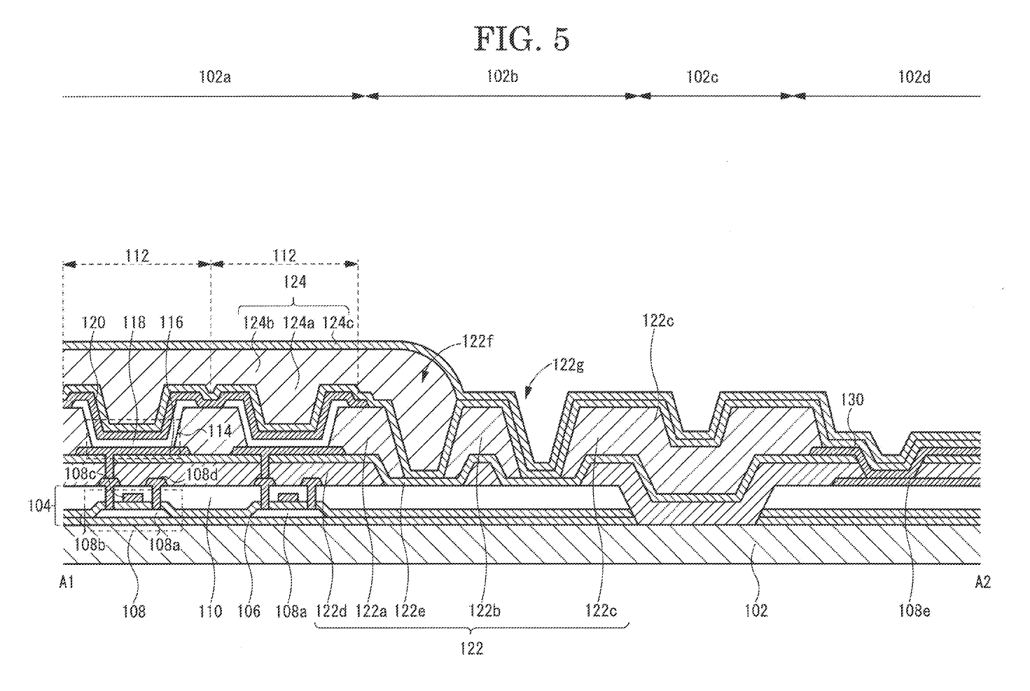

A method of forming the sealing layer 124 is explained while referring to FIG. 5. Here, the sealing layer 124 includes a first inorganic insulating layer 124a, an organic insulating layer 124b and a second inorganic insulating layer 124c. The first inorganic insulating layer 124a is arranged across the surface of the substrate 102. The organic insulating layer 124b is arranged on the first inorganic insulating layer 124a, covers the plurality of pixels 112 and is arranged on the inner side of the second partition wall 122b. The second inorganic insulating layer 124c is arranged on the organic insulating layer 124b and across over the surface.

The first inorganic insulating layer 124a is formed across one surface of the substrate 102. The first inorganic insulating layer 124a can include an inorganic material such as silicon nitride, silicon oxide, or silicon oxynitride and the like, and can be formed by the same method as the under coat layer 106.

The organic insulating layer 124b is formed. The organic insulating layer 124b is formed by application to the inner side of the second partition wall 122b. The organic insulating layer 124b can include an organic resin such as an acrylic resin, a poly-siloxane, a polyimide and a polyester and the like. In addition, the organic insulating layer 124b may be formed to a thickness which provides a flat surface in order to absorb unevenness caused by the partition wall layer 122. The organic insulating layer 124b is preferred to be selectively formed in the display region 102a. That is, the organic insulating layer 124b is preferred to be formed so as not to overlap a connection electrode. The organic insulating layer 124b can be formed by a wet film formation method such as an inkjet method. In this case, the organic insulating layer 124b which is selectively applied to the display region 102a is blocked by the second partition wall 122b and does not spread to the outside thereof.

The second inorganic insulating layer 124c is formed. The second inorganic insulating layer 124c has the same structure as the first inorganic insulating layer 124a and can be formed by the same method. It is also possible to form the second inorganic insulating layer 124c, so it not only covers the organic insulating layer 124b but also the connection electrode. In this way, it is possible to seal the organic insulating layer 124b using the first inorganic insulating layer 124a and the second inorganic insulating layer 124c.

In the manufacturing processes up to above, the sealing layer 124 has a three layer structure including the first inorganic insulating layer 124a, the organic insulating layer 124b and the second inorganic insulating layer 124c on the inner side of the second partition wall 122b, and a two layer structure including the first inorganic insulating layer 124a and the second inorganic insulating layer 124c on the outside of the second partition wall 122b.

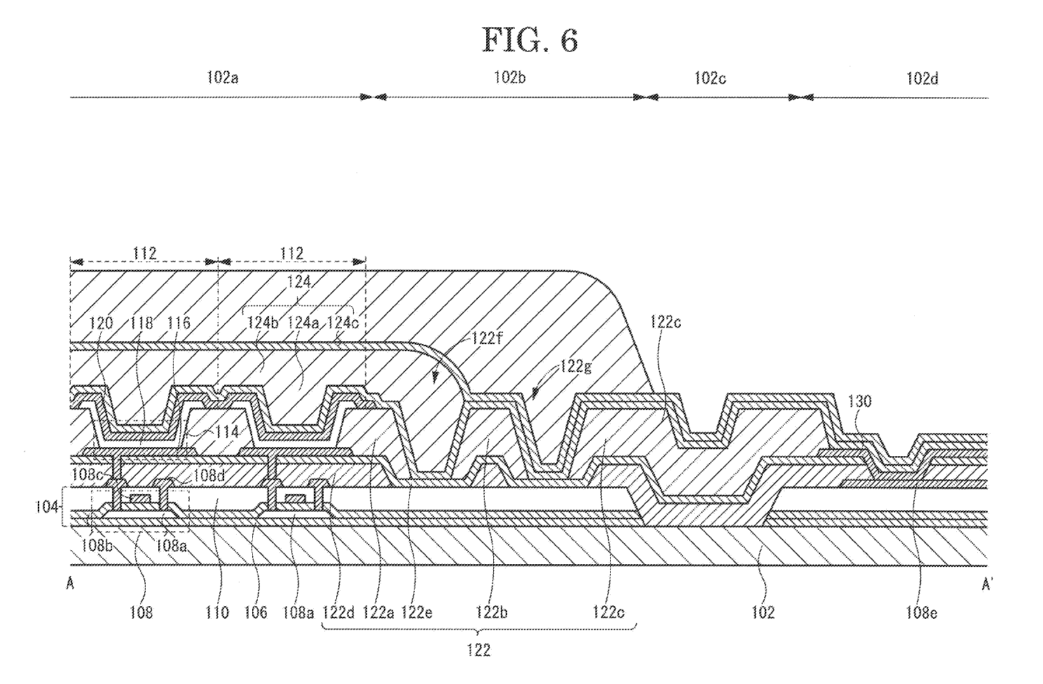

A method of forming the first protective layer 126 is explained while referring to FIG. 6. The first protective layer 126 is arranged on the sealing layer 124 and an end part thereof is arranged on the third partition wall 122c. As is shown in FIG. 6, the first protective layer 126 is preferred to be formed to selectively cover a region where the first inorganic insulating layer 124a and the second inorganic insulating layer 124c contact with each other within the display region 102a, and so that it does not overlap with the connection terminal 130.

The first protective layer 126 can include the same material as the organic insulating layer 124b which forms the sealing layer 124 and can be formed using the same method.

As described above, the periphery shaped groove part 122g is formed between the third partition wall 122c and the second partition wall 122b. The first protective layer 126 fills this periphery shaped groove part 122g. It is possible to increase the film thickness in the end part vicinity of the first protective layer 126 using by the periphery shaped groove part 122g.

The groove part 122g is filled by the first protective layer 126, and it is possible to prevent the first protective layer 126 from flowing further to the outside than the third partition wall 122c using the groove part 122g and the third partition wall 122c. That is, the third partition wall 122c has a blocking function which prevents the first protective layer 126 from spreading to the outside thereof. In this case, since the first protective layer 126 functions as a mask when the sealing layer 124 is later etched, the first protective layer 126 may also slightly extend on the third partition wall 122c.

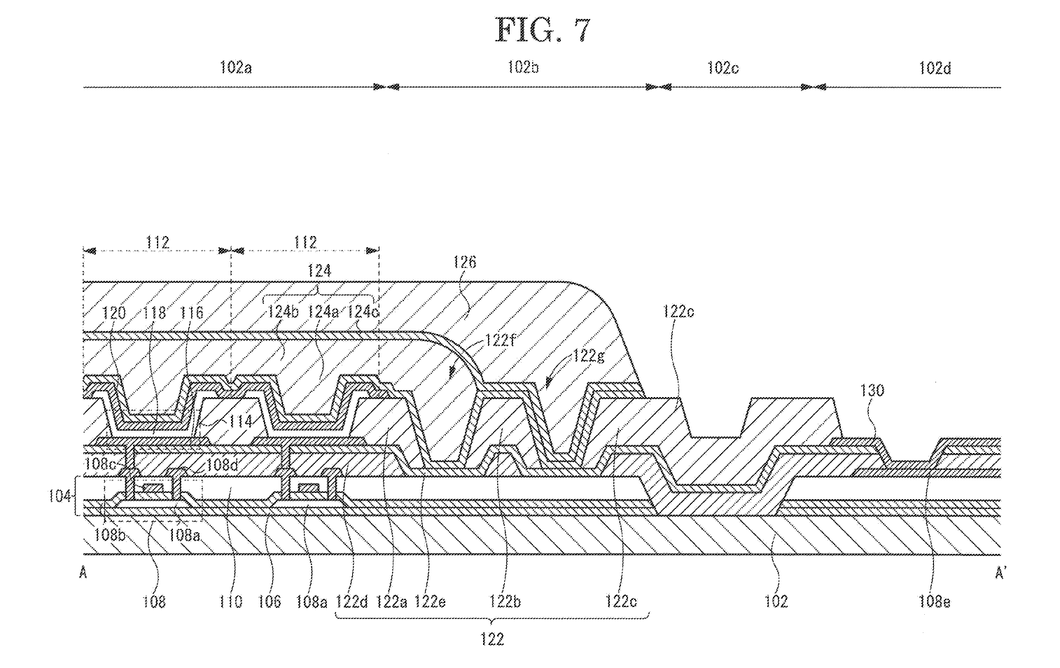

Next, a method of exposing the plurality of connection terminals 130 which are covered by the sealing layer 124 by the processes up to this point is explained while referring to FIG. 7. Here, the sealing layer 124 is etched using the first protective layer 126 as a mask and the plurality of connection terminals 130 is exposed. Here, the region of the sealing layer 124 which is exposed to the first protective layer 126 is a region which includes a two layer structure of the first inorganic insulating layer 124a and the second inorganic insulating layer 124c.

The thickness of the first protective layer 126 is increased in the end part vicinity thereof as described above. As a result, it is possible to suppress the end part of the sealing layer 124 from receding in the process of etching the first protective layer 126. When the end part of the first protective layer 126 recedes too much, there is a concern that the organic insulating layer 124b may be exposed in the etching process of the sealing layer 124 since etching is performed up to the region where the three layers of the first inorganic insulating layer 124a, the organic insulating layer 124b and the second inorganic insulating layer 124c are stacked. When the organic insulating layer 124b is exposed, it becomes an entrance path for moisture and the moisture which has entered the organic insulating layer 124b passes through the first inorganic insulating layer 124a which deteriorates the light emitting layer 118. As a result, the yield and reliability of the display device 100 deteriorate. Since the first inorganic insulating layer 124a is arranged on the partition wall layer 122 which has unevenness, a crack or the like easily occurs which can become an entrance path for moisture.

As a result, if the third partition wall 122c is arranged and the first protective layer 126 which has an end part is formed on the third partition wall 122c, it is possible to increase the film thickness of the end part vicinity of the first protective layer 126 using the groove part 122g between the second partition wall 122b and the third partition wall 122c. In this way, it is possible to suppress the end part of the first protective layer 126 from receding when etching the sealing layer 124. In this way, etching can be performed up to an unintended region of the sealing layer 124 which can prevent the organic insulating layer 124b from being exposed. In addition, it is possible to form the end parts of the first inorganic insulating layer 124a, the second inorganic insulating layer 124c and the first protective layer 126 continuously on the third partition wall 122c. In this way, it is possible to reduce the width of the periphery region 102b.

The second protective layer 128, the polarization plate 132 and the cover film 134 are formed. A polymer material such as polyester, epoxy resin or acrylic resin can be used for the second protective layer 128, and it can be formed by applying a printing method or a laminating method and the like. The same polymer material as the second protective layer 128 can be used for the cover film 134, and in addition to the polymer materials described above, it is also possible to apply a polymer material such as polyolefin or polyimide. Next, a connector is connected at the opening using the anisotropic conductive film 136 or the like and thereby the display device 100 shown in FIG. 1 and FIG. 2 can be formed.

According to the manufacturing method of the display device 100 according to the present embodiment, it is possible to prevent deterioration of the sealing layer 124 in the manufacturing process. In this way, it is possible to provide the display device 100 with improved manufacturing yield and reliability.

Each embodiment described above as embodiments of the present invention can be implemented in combination as appropriate as long as they do not contradict each other. In addition, those skilled in the art could appropriately add, delete or change the design of the constituent elements based on the display device of each embodiment, or add, omit or change conditions as long as it does not depart from the concept of the present invention and such changes are included within the scope of the present invention.

Although the display device using a light emitting element is exemplified as one embodiment in the present specification, other self-light emitting type display devices, liquid crystal display devices, or flat panel type display devices such as an electronic paper type display device including an electrophoresis element can be given as examples. In addition, the structure shown in an embodiment of the present specification can be applied from a medium to small size to a large size display device without any particular limitation.

Even if other actions and effects which are different from the actions and effects brought about by the aspects of each embodiment described above are obvious from the description of the present specification or those which could be easily predicted by those skilled in the art, such actions and effects are to be interpreted as being provided by the present invention.

What is claimed is:

1. A display device comprising:
a plurality of pixels arranged on one surface of a substrate within a display region, each of the plurality of pixels including a light emitting element;
a partition wall layer including a first partition wall, a second partition wall and a third partition wall;
a sealing layer arranged on the plurality of pixels and the partition wall layer, the sealing layer including a first inorganic insulating layer, an organic insulating layer and a second inorganic insulating layer;
a protective layer arranged on the sealing layer; and
a plurality of connection terminals exposed from the protective layer;
wherein
the first partition wall surrounds each of the plurality of pixels;
the second partition wall surrounds the display region;
the third partition wall surrounds the outside of the second partition wall;
a groove part is included between the second partition wall and the third partition wall;
the organic insulating layer is arranged on the first inorganic insulating layer;
the second inorganic insulating layer is arranged on the organic insulating layer;
an end part of the organic insulating layer is arranged between the first partition wall and the second partition wall or on the second partition wall; and
an end part of the first inorganic insulating layer, the second inorganic insulating layer and the protective layer are each arranged further to the outside than an end part of the second partition wall.

2. The display device according to claim 1, wherein a film thickness of the protective layer on the groove part is thicker than a film thickness of the protective layer on the second partition wall and on the third partition wall.

3. The display device according to claim 1, wherein an end part of the first inorganic insulating layer and an end part of the second inorganic insulating layer are each arranged on the third partition wall or on the groove part respectively.

4. The display device according to claim 3, wherein either of an end part of the first inorganic insulating layer and an end part of the second inorganic insulating layer are arranged on the third partition wall.

5. The display device according to claim 3, wherein either of an end part of the first inorganic insulating layer and an end part of the second inorganic insulating layer are arranged on the groove part.

6. The display device according to claim 1, wherein an end part of the first inorganic insulating layer, an end part of the second inorganic insulating layer and end part of the protective layer have a coplanar surface.

7. The display device according to claim 1, wherein the first inorganic insulating layer and the second inorganic insulating layer are in direct contact further to the outside than an end part of the organic insulating layer.

8. The display device according to claim 7, wherein the first inorganic insulating layer and the second inorganic insulating layer are in direct contact at an end part of the organic insulating layer.

9. The display device according to claim 1, wherein the light emitting element is stacked with a first electrode, a light emitting layer and a second electrode from the substrate side, and the first partition wall covers a periphery edge of a surface on the light emitting layer side of the first electrode.

10. The display device according to claim 1, wherein the partition wall layer further includes a planarized insulating layer arranged on a lower layer than the light emitting element.

11. The display device according to claim 1, wherein the third partition wall has a maximum film thickness of 1 μm or more and 5 μm or less.

12. The display device according to claim 1, wherein the second partition wall has a maximum film thickness of 1 μm or more and 5 μm or less.

13. The display device according to claim 1, wherein a gap in a direction parallel to one surface of the substrate between the first partition wall and the second partition wall is 10 μm or more and 500 μm or less.

14. The display device according to claim 1, wherein a gap in a direction parallel to one surface of the substrate between the second partition wall and the third partition wall is 10 μm or more and 500 μm or less.

15. The display device according to claim 1, wherein a width of the second partitional wall is 5 μm or more and 200 μm or less.

16. A method for manufacturing a display device, the method comprising:
forming a display region including a plurality of pixels, each of the plurality of pixels including a light emitting element, a partition wall layer including a first partition wall covering a periphery edge of each of the plurality of pixels, a second partition wall surrounding the display region, and a third partition wall surrounding the second partition wall, and a plurality of connection terminals on the outside of the third partition wall on one surface of a substrate;
forming a sealing layer including a first inorganic insulating layer on the plurality of pixels and the partition wall layer, an organic insulating layer having an end part arranged on an inner side of the second partition wall on the first inorganic insulating layer, and a second inorganic insulating layer on the organic insulating layer;
etching the first inorganic insulating layer and the second inorganic insulating layer so that an end part of each is further to the outside than the second partition wall;
forming a protective layer on the sealing layer so that an end part thereof is on the third partition wall; and
etching the sealing layer exposed from the protective layer using the protective layer as a mask and exposing a plurality of connection terminals.

17. The method according to claim 16, wherein the organic insulating layer is formed by coating on an inner side of the second partition wall.

18. The method according to claim 16, wherein the third partition wall is formed surrounding the outside of the second partition wall so that a groove part is formed between the second partition wall and the third partition wall.

19. The method according to claim 16, wherein a film thickness of the protective layer on the groove part is formed larger than a film thickness of the protective layer on the second partition wall and on the third partition wall.

20. The method according to claim 16, wherein an end part of the first inorganic insulating layer and the second inorganic insulating layer are each formed an end part of the third partition wall or on the groove part respectively.
